(19) United States
(12) Patent Application Publication
(10) Pub. No.: US 2024/0305279 A1
(43) Pub. Date: Sep. 12, 2024

(54) DATA LATCH CIRCUIT, SEMICONDUCTOR DEVICE, AND SEMICONDUCTOR STORAGE DEVICE

(71) Applicant: Kioxia Corporation, Tokyo (JP)

(72) Inventors: Toshifumi WATANABE, Yokohama (JP); Kiyofumi SAKURAI, Yokohama (JP); Teppei HIGASHITSUJI, Fujisawa (JP); Takumi KOSAKI, Kamakura (JP); Eiji KOZUKA, Chuo (JP)

(73) Assignee: Kioxia Corporation, Tokyo (JP)

(21) Appl. No.: 18/460,030

(22) Filed: Sep. 1, 2023

(30) Foreign Application Priority Data
Mar. 10, 2023 (JP) 2023-037895

(51) Int. Cl. H03K 3/356; G11C 16/04; G11C 16/26; G11C 16/30

(52) U.S. Cl. CPC H03K 3/356017; G11C 16/0483; G11C 16/26; G11C 16/30

(57) ABSTRACT

A data latch circuit according to embodiments described herein includes a first circuit and a second circuit. The first circuit has a first transistor with a first conductivity type and a second transistor with a second conductivity type that differs from the first conductivity type being connected in series and stores a first logical value. The second circuit has a third transistor with the first conductivity type and a fourth transistor with the second conductivity type being connected in series and stores a second logical value being an inversion of the first logical value. The data latch circuit enables one of a first voltage and a second voltage that differs from the first voltage to be applied to back gates of the first transistor and the third transistor and enables a third voltage to be applied to sources of the first transistor and the third transistor.

### CROSS-REFERENCE TO RELATED APPLICATION

This application is based upon and claims the benefit of priority from the prior Japanese Patent Application No. 2023-37895 filed on Mar. 10, 2023; the entire contents of which are incorporated herein by reference.

### FIELD

Embodiments described herein relate generally to a data latch circuit, a semiconductor device, and a semiconductor storage device.

### BACKGROUND

A NAND memory is known as a type of a semiconductor storage device.

### BRIEF DESCRIPTION OF THE DRAWINGS

FIG. 1 is a block diagram showing an example of a configuration of a memory system;

FIG. 2 is a block diagram showing an example of a non-volatile memory 2 shown in FIG. 1;

FIG. 3 is a diagram showing an example of a configuration of blocks in a memory cell array 20 with a three-dimensional structure;

FIG. 4 is a block diagram showing an example of a sense amplifier unit group 28 and a data register 29 shown in FIG. 2;

FIG. 5 is a circuit diagram showing an example of a configuration of a data latch circuit according to a comparative example;

FIG. 6 is a waveform chart showing an example of a signal variation during data transfer according to the comparative example;

FIG. 7 is a circuit diagram showing an example of a configuration of a data latch circuit according to a first embodiment;

FIG. 8 is a waveform chart showing an example of a signal variation during data transfer according to the first embodiment;

FIG. 9 is a diagram showing an example of a connection between a data latch circuit and a power supply circuit according to a second embodiment;

FIG. 10 is a circuit diagram showing an example of a configuration of a data latch circuit according to a third embodiment;

FIG. 11 is a waveform chart showing an example of a signal variation during data transfer according to the third embodiment;

FIG. 12 is a circuit diagram showing an example of a configuration of a data latch circuit according to a fourth embodiment;

FIG. 13 is a waveform chart showing an example of a signal variation during data transfer according to the fourth embodiment;

FIG. 14 is a diagram showing an example of a configuration of a data latch circuit according to a fifth embodiment;

FIG. 15 is a waveform chart showing an example of a signal variation during data transfer according to the fifth embodiment;

FIG. 16 is a diagram showing an example of a connection between a data latch circuit and a power supply circuit according to a sixth embodiment;

FIG. 17 is a diagram showing an example of a configuration of a data latch circuit according to a seventh embodiment;

FIG. 18 is a waveform chart showing an example of a signal variation during data transfer according to the seventh embodiment;

FIG. 19 is a diagram showing an example of a configuration of a data latch circuit according to an eighth embodiment; and

FIG. 20 is a waveform chart showing an example of a signal variation during data transfer according to the eighth embodiment.

### DETAILED DESCRIPTION

A data latch circuit according to embodiments described herein includes a first circuit and a second circuit. The first circuit has a first transistor with a first conductivity type and a second transistor with a second conductivity type that differs from the first conductivity type being connected in series and stores a first logical value. The second circuit has a third transistor with the first conductivity type and a fourth transistor with the second conductivity type being connected in series and stores a second logical value being an inversion of the first logical value. The data latch circuit enables one of a first voltage and a second voltage that differs from the first voltage to be applied to back gates of the first transistor and the third transistor and enables a third voltage to be applied to sources of the first transistor and the third transistor.

Hereinafter, embodiments of the present invention will be described in detail with reference to the drawings.

### First Embodiment

### Configuration of Memory System

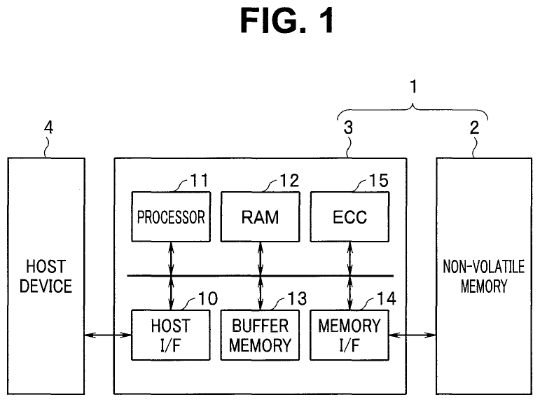

FIG. 1 is a block diagram showing an example of a configuration of a memory system. A memory system 1 according to the present embodiment includes a memory controller 3 and a non-volatile memory 2. Note that the non-volatile memory 2 may include a plurality of memory chips. The memory system 1 is capable of connecting to a host device 4. For example, the host device 4 is an electronic device such as a personal computer or a mobile terminal.

The memory system 1 may be configured by mounting a plurality of chips constituting the memory system 1 on a motherboard having been mounted with the host device 4 or configured as a system LSI (large-scale integrated circuit) or an SoC (system-on-a-chip) which realizes the memory system 1 with one module. Examples of the memory system 1 include a memory card such as an SD card, an SSD (solid-state-drive), and an eMMC (embedded-multi-media card).

The non-volatile memory 2 is a NAND memory including a plurality of memory cells and stores data in a non-volatile manner. The non-volatile memory 2 is an example of a semiconductor device. A specific configuration of the non-volatile memory 2 will be described later.

The memory controller 3 issues write (also referred to as program), read, erase, and other instructions to the non-volatile memory 2 in response to, for example, an instruction from the host device 4. In addition, the memory controller 3 manages a memory space of the non-volatile memory 2. The memory controller 3 includes a host interface (host I/F) circuit 10, a processor 11, a RAM (random access memory) 12, a buffer memory 13, a memory interface (memory I/F) circuit 14, an ECC (error checking and correcting) circuit 15, and the like.

The host I/F circuit 10 is connected to the host device 4 via a host bus and performs interface processing with the host device 4. In addition, the host I/F circuit 10 transmits and receives instructions, addresses, and data to and from the host device 4.

The processor 11 is constituted of, for example, a CPU (central processing unit). The processor 11 controls operations of the entire memory controller 3. For example, when the processor 11 receives a write instruction from the host device 4, the processor 11 issues a write instruction in accordance with the write instruction from the host device 4 to the non-volatile memory 2 via the memory I/F circuit 14.

The processor 11 executes similar processing in cases of read and erase. In addition, the processor 11 executes various kinds of processing for managing the non-volatile memory 2 such as wear leveling.

The RAM 12 is used as a work area of the processor 11 and stores firmware data loaded from the non-volatile memory 2, various tables created by the processor 11, and the like. For example, the RAM 12 is constituted of a DRAM or an SRAM.

The buffer memory 13 temporarily stores data transmitted from the host device 4 and temporarily stores data transmitted from the non-volatile memory 2.

The memory I/F circuit 14 is connected to the non-volatile memory 2 via a bus and performs interface processing with the non-volatile memory 2. In addition, the memory I/F circuit 14 transmits and receives instructions, addresses, and data to and from the non-volatile memory 2.

During data write, the ECC circuit 15 generates an error correction code with respect to data to be written, adds the error correction code to the data to be written, and sends the data to be written to the memory I/F circuit 14. In addition, during data read, the ECC circuit 15 performs error detection and/or error correction with respect to the read data using an error correction code included in the read data. Note that the ECC circuit 15 may be provided inside the memory I/F circuit 14.

### Configuration of Non-Volatile Memory

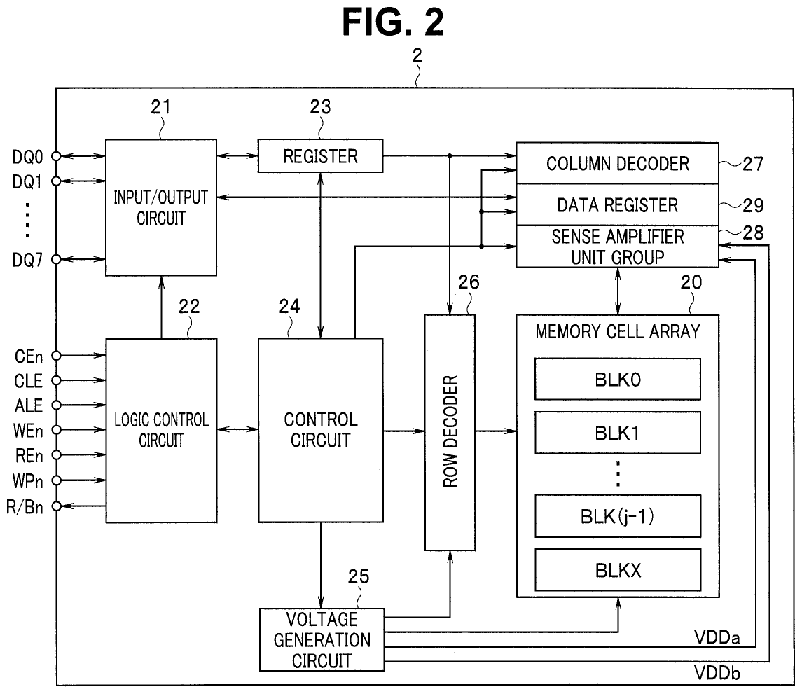

FIG. 2 is a block diagram showing an example of the non-volatile memory 2 shown in FIG. 1. The non-volatile memory 2 includes a memory cell array 20, an input/output circuit 21, a logic control circuit 22, a register 23, a control circuit 24, a voltage generation circuit 25, a row decoder 26, a column decoder 27, a sense amplifier unit group 28, and a data register (data cache) 29.

The memory cell array 20 includes j-number of blocks BLK0 to BLK (j−1) and a block BLKX, where j is an integer of 1 or more. Each of the plurality of blocks BLK includes a plurality of memory cell transistors. The memory cell transistors constitute a memory cell configured to be electrically rewritable. A plurality of bit lines BL, a plurality of word lines WL, a source line CELSRC, and the like are arranged in the memory cell array 20 in order to control voltage applied to the memory cell transistors. A specific configuration of the blocks BLK will be described later.

The input/output circuit 21 and the logic control circuit 22 are connected to the memory controller 3 via a bus. The input/output circuit 21 transmits and receives signals DQ (for example, DQ0 to DQ7) to and from the memory controller 3 via the bus.

The logic control circuit 22 receives, from the memory controller 3 via the bus, external control signals (for example, a chip enable signal CEn, a command latch enable signal CLE, an address latch enable signal ALE, a write enable signal WEn, a read enable signal REn, and a write protect signal WPn). The letter n added to the signal names indicates an active row. In addition, the logic control circuit 22 transmits a ready/busy signal R/Bn to the memory controller 3 via the bus.

In a system configuration in which a plurality of non-volatile memories 2 are used, the signal CEn is a signal used to select a specific non-volatile memory 2 and change the selected non-volatile memory 2 to enable. The signal CLE enables a command transmitted as a signal DQ to latch to the register 23. The signal ALE enables an address transmitted as a signal DQ to latch to the register 23. The signal WEn enables write. The signal REn enables read. The signal WPn prohibits write and erase. The signal R/Bn indicates, when a basic operation command is being used, whether the non-volatile memory 2 is in a ready state (a state where an instruction from the outside can be accepted) where write, read, and erase operations are not being performed or in a busy state (a state where an instruction from the outside cannot be accepted).

The register 23 includes a command register, an address register, a status register, and the like. The command register temporarily stores a command. The address register temporarily stores an address. The status register temporarily stores data necessary for operations of the non-volatile memory 2. For example, the register 23 is constituted of an SRAM.

The control circuit 24 receives a command from the register 23 and integrally controls the non-volatile memory 2 in accordance with a sequence based on the command.

The voltage generation circuit 25 receives power supply voltage from the outside of the non-volatile memory 2 and, using the power supply voltage, generates a plurality of voltages (power) necessary for a write operation, a read operation, and an erase operation. The voltage generation circuit 25 supplies the memory cell array 20, the row decoder 26, the sense amplifier unit group 28, and the like with the plurality of generated voltages (power). For example, the voltage generation circuit 25 generates power VDDa with a higher voltage than power VDD and power VDDb with a lower voltage than the power VDD and supplies the sense amplifier unit group 28 with the power VDDa and VDDb. The power VDDa is supplied to a power supply circuit 70 to be described later and the power VDDb is supplied to a power supply circuit 80 to be described later.

The row decoder 26 receives a row address from the register 23 and decodes the row address. Based on the decoded row address, the row decoder 26 performs a selection operation of a word line. A word line to which a memory cell transistor MT to be a target of write and read is connected is referred to as a selected word line. In addition, the row decoder 26 transfers a plurality of voltages necessary for a write operation, a read operation, and an erase operation to the selected block BLK.

The column decoder 27 receives a column address from the register 23 and decodes the column address. Based on the decoded column address, the column decoder 27 supplies each bit line BL with a predetermined voltage.

During read of data, the sense amplifier unit group 28 detects and amplifies data read from a memory cell transistor to a bit line. In addition, during write of data, the sense amplifier unit group 28 supplies the bit line BL with write data.

During read of data, the data register 29 temporarily stores data transferred from the sense amplifier unit group 28 and serially transfers the data to the input/output circuit 21. In addition, during write of data, the data register 29 temporarily stores data serially transferred from the input/output circuit 21 and transfers the data to the sense amplifier unit group 28. The data register 29 is constituted of an SRAM or the like.

### Block Configuration of Memory Cell Array

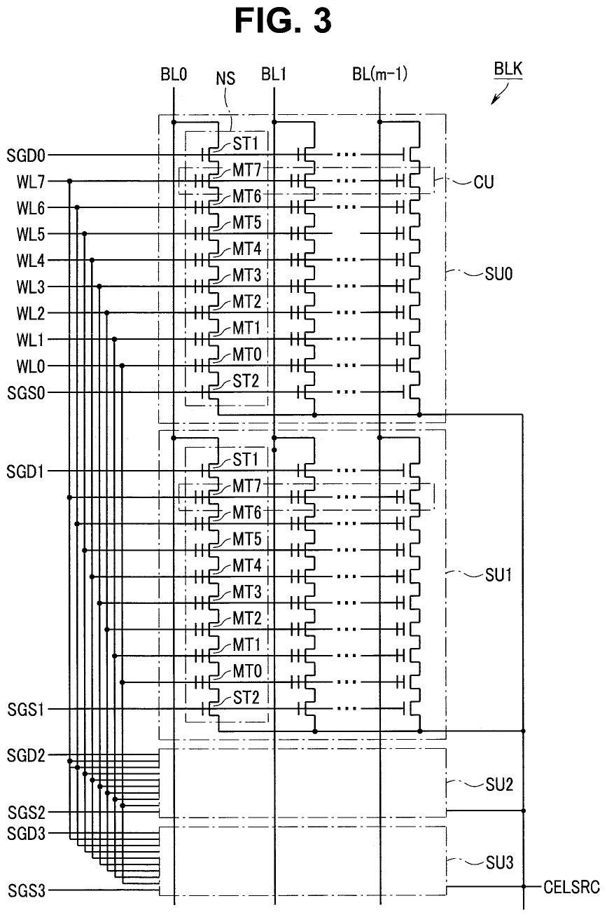

FIG. 3 is a diagram showing an example of a configuration of blocks in the memory cell array 20 with a three-dimensional structure. FIG. 3 shows one block BLK among a plurality of blocks constituting the memory cell array 20. Other blocks of the memory cell array have a similar configuration to the configuration shown in FIG. 3.

As illustrated, for example, the block BLK includes four string units SU0 to SU3 (hereinafter, the string units SU0 to SU3 will be typically referred to as a string unit SU). In addition, each string unit SU has a NAND string NS including a plurality of memory cell transistors MT (MT0 to MT7) and selected gate transistors ST1 and ST2. While the number of the memory cell transistors MT included in the NAND string NS is eight in FIG. 3, there may be more memory cell transistors MT. While the selected gate transistors ST1 and ST2 are shown as one transistor on an electric circuit, the selected gate transistors ST1 and ST2 may be the same as the memory cell transistors in terms of structure. In addition, as the selected gate transistors ST1 and ST2, a plurality of selected gate transistors may be respectively used. Furthermore, a dummy cell transistor may be provided between the memory cell transistors MT and the selected gate transistors ST1 and ST2.

The memory cell transistors MT are arranged between the selected gate transistors ST1 and ST2 so as to be connected in series. The memory cell transistor MT7 on one end side (a bit line side) is connected to the selected gate transistor ST1 and the memory cell transistor MT0 on another end side (a source line side) is connected to the selected gate transistor ST2.

Gates of the selected gate transistors ST1 of the respective string units SU0 to SU3 are each connected to selected gate lines SGD0 to SGD3 (hereinafter, the selected gate lines SGD0 to SGD3 will be typically referred to as a selected gate line SGD). In addition, gates of the selected gate transistors ST2 of the respective string units SU0 to SU3 are each connected to selected gate lines SGS0 to SGS3 (hereinafter, the selected gate lines SGS0 to SGS3 will be typically referred to as a selected gate line SGS). Note that gates of the plurality of selected gate transistors ST2 in each block BLK may be connected to a common selected gate line SGS.

Gates of the memory cell transistors MT0 to MT7 in the same block BLK are each commonly connected to word lines WL0 to WL7. In other words, in contrast to the word lines WL0 to WL7 being commonly connected among the plurality of string units SU0 to SU3 in the same block BLK, the selected gate line SGD is independent for each of the string units SU0 to SU3 even in the same block BLK. A gate of the memory cell transistor MTi in a same row in the block BLK is connected to the same word line WLi.

Each NAND string NS is connected to a corresponding bit line. Therefore, each memory cell transistor MT is connected to a bit line via the selected gate transistors ST1 and ST2 and the other memory cell transistors MT included in the NAND string NS. Generally, data in memory cell transistors MT in the same block BLK are collectively erased. On the other hand, read and write of data are, typically, collectively performed with respect to a plurality of memory cell transistors MT commonly connected to one word line WL arranged in one string unit SU. A set of such memory cell transistors MT sharing a word line WL in one string unit SU will be referred to as a cell unit CU.

A write operation to a cell unit CU is executed in units of pages. For example, when each cell is a TLC (Triple Level Cell) capable of storing 3-bit (8-level) data, one cell unit CU can store three pages' worth of data. The three bits that each memory cell transistor MT can store respectively correspond to the three pages.

### Configuration of Sense Amplifier Unit and Data Register

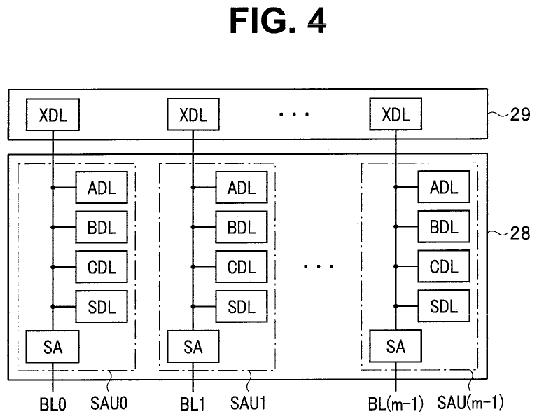

FIG. 4 is a block diagram showing an example of the sense amplifier unit group 28 and the data register 29 shown in FIG. 2.

The sense amplifier unit group 28 includes sense amplifier units SAU0 to SAU(m−1) (hereinafter, the sense amplifier units SAU0 to SAU (m−1) will be typically referred to as a sense amplifier unit SAU) which correspond to the bit lines BL0 to BL(m−1). Each sense amplifier unit SAU includes a sense amplifier SA and data latch circuits SDL, ADL, BDL, and CDL. The sense amplifier SA and the data latch circuits SDL, ADL, BDL, and CDL are connected so as to be able to transfer data to each other.

The data latch circuits SDL, ADL, BDL, and CDL temporarily store data. During a write operation, the sense amplifier SA controls a voltage of the bit line BL in accordance with data stored in the data latch circuit SDL. The data latch circuits ADL, BDL, and CDL are used in multi-level operations in which the memory cell transistor MT stores data of 2 bits or more. Specifically, the data latch circuit ADL is used to store write data for a lower page. The data latch circuit BDL is used to store write data for a middle page. The data latch circuit CDL is used to store write data for an upper page. The number of data latch circuits included in the sense amplifier unit SAU is determined in accordance with the number of bits stored in one memory cell transistor MT.

During a read operation, the sense amplifier SA senses data read to a corresponding bit line BL and determines whether the data is 0 data or 1 data. In addition, during a write operation, the sense amplifier SA applies a voltage to the bit line BL based on the write data.

The data register 29 includes as many data latch circuits XDL as the sense amplifier units SAU0 to SAU (m−1). The data latch circuits XDL are connected to the input/output circuit 21. The data latch circuits XDL temporarily store write data sent from the input/output circuit 21 and temporarily store read data sent from the sense amplifier units SAU. More specifically, data transfer between the input/output circuit 21 and the sense amplifier unit group 28 is performed via one page's worth of the data latch circuits XDL. The write data received by the input/output circuit 21 is transferred to any of the data latch circuits ADL, BDL, and CDL via the data latch circuits XDL. The read data read by the sense amplifier SA is transferred to the input/output circuit 21 via the data latch circuits XDL.

### Specific Configuration of Data Latch Circuit

A configuration of a data latch circuit according to a comparative example will be described before describing a configuration of the data latch circuit according to the present embodiment.

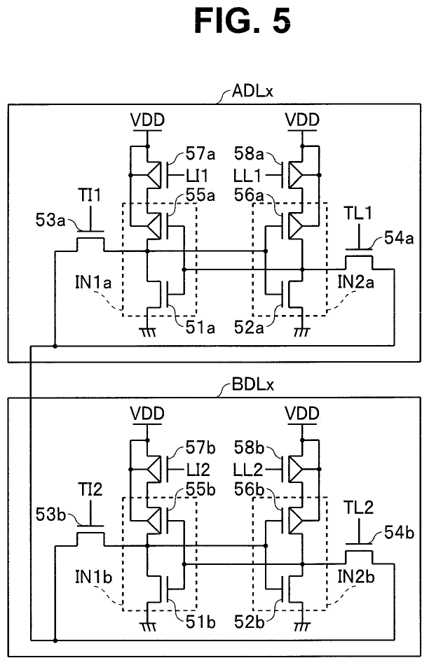

FIG. 5 is a circuit diagram showing an example of the configuration of the data latch circuit according to the comparative example.

A data latch circuit ADLx includes NMOS transistors 51a to 54a and PMOS transistors 55ato 58a. The NMOS transistors 51a and 52a constitute first and second drive transistors. In addition, the NMOS transistors 53a and 54a constitute first and second transfer transistors. In addition, the PMOS transistors 55aand 56a constitute first and second load transistors.

An inverter IN1a is constituted of the NMOS transistor 51a and the PMOS transistor 55a, and an inverter IN2a is constituted of the NMOS transistor 52a and the PMOS transistor 56a.

The inverters IN1a and IN2a and the NMOS transistors 53a and 54a share a same circuit configuration as an SRAM. In other words, the data latch circuit ADLx is configured by adding the PMOS transistors 57a and 58a to the same circuit configuration as an SRAM. As will be described later, the PMOS transistors 57aand 58a constitute first and second control transistors for increasing a transfer margin and a transfer rate.

An input terminal of the inverter IN1a is connected to an output terminal of the inverter IN2a . In addition, an input terminal of the inverter IN2a is connected to an output terminal of the inverter IN1a.

The NMOS transistors 53a and 54a are respectively connected to the output terminals of the inverters IN1a and IN2a. Control signals TI1 and TL1 are respectively inputted to gates of the NMOS transistors 53a and 54a. On/off states of the NMOS transistors 53a and 54a are respectively controlled by the control signals TI1 and TL1.

The PMOS transistors 57a and 58a are respectively connected between the PMOS transistors 55aand 56a and the power VDD. The power VDD is supplied to respective sources and back gates of the PMOS transistors 57a and 58a. The back gates of the PMOS transistors 57a and 58a are substrates.

Control signals LI1 and LL1 are respectively inputted to gates of the PMOS transistors 57a and 58a. On/off states of the PMOS transistors 57a and 58a are respectively controlled by the control signals LI1 and LL1.

A data latch circuit BDLx includes NMOS transistors 51b to 54b and PMOS transistors 55b to 58b. An inverter IN1b is constituted of the NMOS transistor 51b and the PMOS transistor 55b, and an inverter IN2b is constituted of the NMOS transistor 52b and the PMOS transistor 56b.

Control signals TI2 and TL2 are respectively inputted to gates of the NMOS transistors 53b and 54b. On/off states of the NMOS transistors 53b and 54b are respectively controlled by the control signals TI2 and TL2.

Control signals LI2 and LL2 are respectively inputted to gates of the PMOS transistors 57b and 58b. On/off states of the PMOS transistors 57b and 58b are respectively controlled by the control signals LI2 and LL2. Since other circuit components are similar to the components of the data latch circuit ADLx, description thereof will not be repeated.

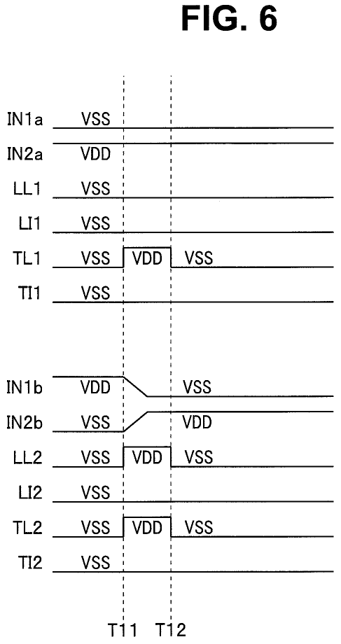

FIG. 6 is a waveform chart showing an example of a signal variation during data transfer according to the comparative example.

The waveform chart shown in FIG. 6 is a waveform chart when transferring data from the data latch circuit ADLx to the data latch circuit BDLx. In FIG. 6, data is transferred between time points T11 to T12.

When transferring data from the data latch circuit ADLx to the data latch circuit BDLx, at the time point T11, the control signals TL1 and TL2 are raised from a low level to a high level. Accordingly, the NMOS transistor 54a of the data latch circuit ADLx and the NMOS transistor 54b of the data latch circuit BDLx are turned on and output of the inverter IN2a of the data latch circuit ADLx is inputted to the inverter IN1b of the data latch circuit BDLx.

In addition, at the time point T11, the control signal LL2 inputted to the gate of the PMOS transistor 58b of the data latch circuit BDLx to which data is to be transferred is raised from a low level to a high level. Accordingly, by turning off the PMOS transistor 58b of the data latch circuit BDLx and suppressing performance of the PMOS transistor 56b, a transfer margin and a transfer rate when transferring data from the data latch circuit ADLx to the data latch circuit BDLx are increased.

However, with the data latch circuits ADLx and BDLx (and, similarly, the other data latch circuits) according to the comparative example, adding the PMOS transistors 57a, 58a, 57b, and 58b being control transistors for increasing the transfer margin and the transfer rate to a same circuit configuration as an SRAM resulted in an increase in circuit area.

In contrast, with the data latch circuits ADL and BDL (and, similarly, the other data latch circuits) according to the present embodiment, circuit area has been reduced compared to the data latch circuits ADLx and BDLx according to the comparative example despite increasing the transfer margin and the transfer rate.

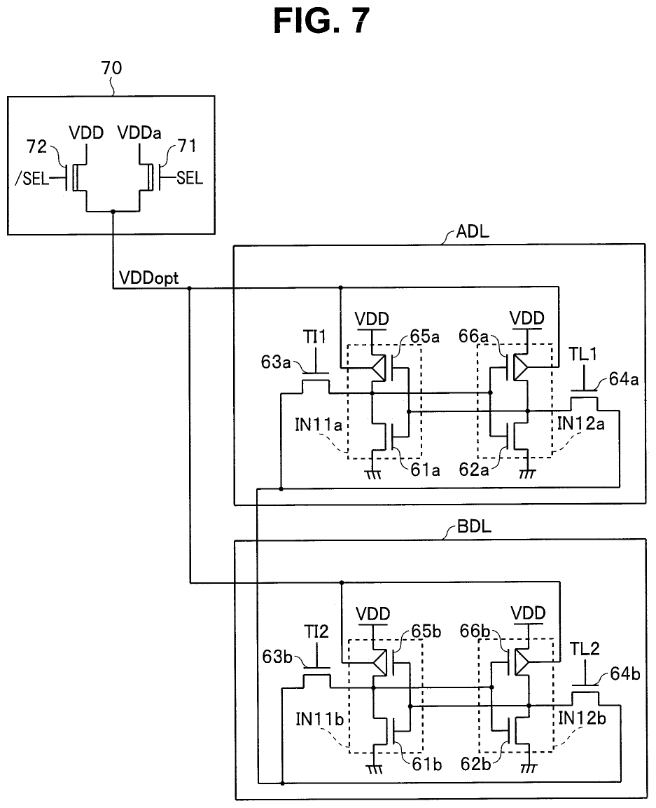

Next, a configuration of the data latch circuit of the present embodiment will be described. FIG. 7 is a circuit diagram showing an example of the configuration of the data latch circuit according to the first embodiment.

The data latch circuit ADL includes NMOS transistors 61a to 64a and PMOS transistors 65a and 66a. The NMOS transistors 61a and 62a constitute first and second drive transistors. In addition, the NMOS transistors 63a and 64a constitute first and second transfer transistors. In addition, the PMOS transistors 65a and 66a constitute first and second load transistors.

An inverter IN11a is constituted of the NMOS transistor 61a and the PMOS transistor 65a, and an inverter IN12a is constituted of the NMOS transistor 62a and the PMOS transistor 66a.

The power VDD is supplied to sources of the PMOS transistors 65a and 66a. In addition, power VDDopt is supplied to back gates of the PMOS transistors 65a and 66a.

As described above, the data latch circuit ADL is configured by deleting the PMOS transistors 57a and 58a for control from the data latch circuit ADLx according to the comparative example. In addition, different power is supplied to the sources and the back gates of the PMOS transistors 65a and 66a.

The inverter IN11a being a first circuit includes the PMOS transistor 65a being a first conductivity type transistor and the NMOS transistor 61a being a second conductivity type transistor and constitutes a first data latch unit configured to store a first logical value.

The inverter IN12a being a second circuit includes the PMOS transistor 66a being a third conductivity type transistor and the NMOS transistor 62a being a fourth conductivity type transistor and constitutes a second data latch unit configured to store a second logical value being an inversion of the first logical value.

In addition, one of the power VDD being a first power supply and the power VDDopt being a second power supply of which a voltage differs from the first power supply is supplied to the back gates of the PMOS transistor 65a and the PMOS transistor 66a. In addition, power VDD being a third power supply is supplied to the sources of the PMOS transistor 65a and the PMOS transistor 66a. The voltage of the first power supply and the voltage of the third power supply have a same potential.

The data latch circuit BDL has a similar configuration to the data latch circuit ADL and includes NMOS transistors 61b to 64b and PMOS transistors 65b and 66b. An inverter IN11b is constituted of the NMOS transistor 61b and the PMOS transistor 65b, and an inverter IN12b is constituted of the NMOS transistor 62b and the PMOS transistor 66b.

The power supply circuit 70 configured to generate the power VDDopt connects the power VDD and power VDDa of which a voltage is higher than the power VDD to each other using depletion NMOS transistors 71 and 72. The power VDD is, for example, 1.5 V, and the power VDDa is, for example, 2.0 V to 2.2 V.

Note that the power supply circuit 70 is not limited to the depletion NMOS transistors 71 and 72 and may be configured using enhance NMOS transistors. In addition, the power supply circuit 70 may be provided inside the voltage generation circuit 25 or provided inside the sense amplifier unit group 28.

A control signal SEL is supplied to a gate of the NMOS transistor 71 and a control signal/SEL is supplied to a gate of the NMOS transistor 72. The control signal/SEL is a signal obtained by inverting the control signal SEL. Accordingly, of the NMOS transistors 71 and 72, one is turned on while the other is turned off.

When the control signal SEL is at a high level, the NMOS transistor 71 is turned on and the NMOS transistor 72 is turned off. Accordingly, the power VDDa is supplied to the back gates of the PMOS transistors 65a, 66a, 65b, and 66b as the power VDDopt.

On the other hand, when the control signal SEL is at a low level, the NMOS transistor 72 is turned on and the NMOS transistor 71 is turned off. Accordingly, the power VDD is supplied to the back gates of the PMOS transistors 65a, 66a, 65b, and 66b as the power VDDopt.

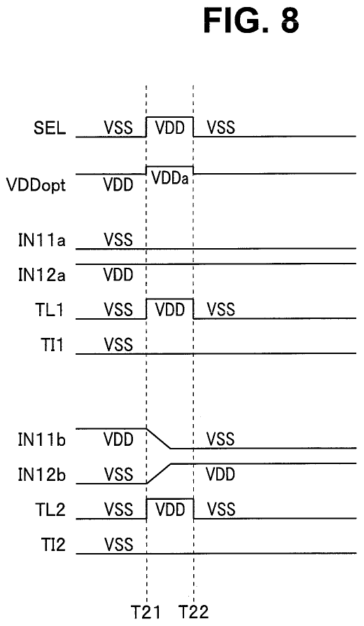

FIG. 8 is a waveform chart showing an example of a signal variation during data transfer according to the first embodiment.

The waveform chart shown in FIG. 8 is a waveform chart when transferring data from the data latch circuit ADL to the data latch circuit BDL. In FIG. 8, data is transferred between time points T21 to T22.

When transferring data from the data latch circuit ADL to the data latch circuit BDL, at the time point T21, the control signals TL1 and TL2 are raised from a low level to a high level. Accordingly, the NMOS transistor 64a of the data latch circuit ADL and the NMOS transistor 64b of the data latch circuit BDL are turned on and output of the inverter IN12a of the data latch circuit ADL is inputted to the inverter IN11b of the data latch circuit BDL.

In addition, when not transferring data, the low-level control signal SEL is inputted to the power supply circuit 70. Accordingly, the NMOS transistor 72 is turned on, the NMOS transistor 71 is turned off, and the power VDD is inputted to the back gates of the PMOS transistors 65a, 66a, 65b, and 66b.

On the other hand, when transferring data, the high-level control signal SEL is inputted to the power supply circuit 70. Accordingly, the NMOS transistor 71 is turned on, the NMOS transistor 72 is turned off, and the power VDDa is inputted to the back gates of the PMOS transistors 65a, 66a, 65b, and 66b.

In other words, the power VDDa with a higher voltage than the power VDD is inputted to the back gates of the PMOS transistors 65a, 66a, 65b, and 66b only during data transfer. Accordingly, when transferring data between the data latch circuits ADL and BDL, a well potential of the PMOS transistor 66b of the data latch circuit BDL to which the data is transferred is raised. As a result, in the data latch circuit BDL, performance of the PMOS transistor 66b is suppressed and the transfer margin and the transfer rate can be increased.

In addition, by raising well potentials of the PMOS transistors 65a, 66a, and 65b other than the PMOS transistor 66b, a standby current of the data latch circuits ADL and BDL can be reduced.

Furthermore, with the data latch circuit ADL (and, similarly, the other data latch circuits), deleting the PMOS transistors 57a and 58a from the data latch circuit ADLx according to the comparative example results in a reduced area.

As described above, with advances in multileveling and high integration, the number of data latch circuits arranged inside the non-volatile memory 2 increases. In the present embodiment, since two PMOS transistors can be reduced from each of a large number of arranged data latch circuits ADL, BDL, . . . , a circuit area of the non-volatile memory 2 can also be significantly reduced.

As described above, with the data latch circuit according to the present embodiment, a circuit area can be reduced while increasing a transfer margin and a transfer rate.

### Second Embodiment

Next, a second embodiment will be described.

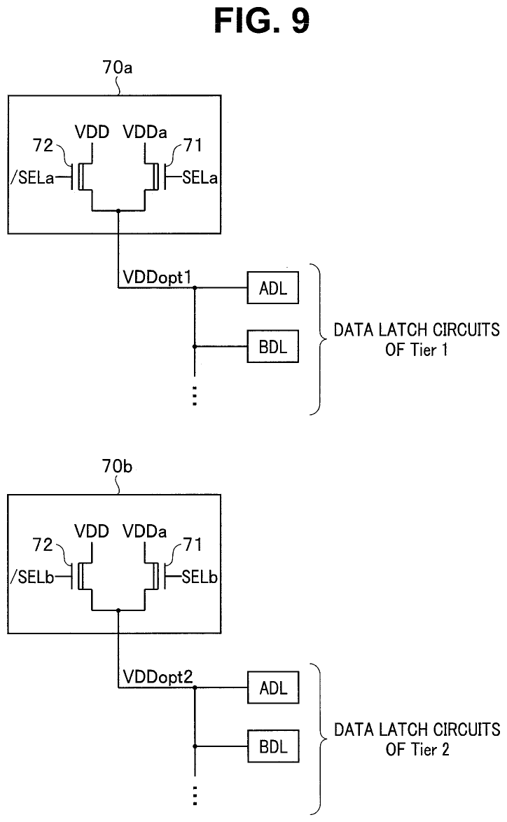

FIG. 9 is a diagram showing an example of a connection between a data latch circuit and a power supply circuit according to the second embodiment.

Sense amplifiers SA and data latch circuits ADL and BDL are arranged in units referred to as tiers for each control signal. In this case, a tier is a unit in which sense amplifier units SAU and data latch circuits ADL, BDL, . . . are physically arranged in rows. In the first embodiment, the same power VDDopt is supplied to all data latch circuits ADL and BDL. Therefore, in the first embodiment, even nodes of back gates of PMOS transistors of data latch circuits that are not operating end up being charged and current consumption increases.

In the second embodiment, power supplies are divided for each tier to prevent power from being supplied to data latch circuits that are not in use and an increase in current consumption is suppressed. In other words, in the second embodiment, a plurality of data latch circuits are divided into a plurality of groups and a power supply circuit is provided for each group made up of a plurality of data latch circuits.

As shown in FIG. 9, a power supply circuit 70a supplies the data latch circuits ADL, BDL, . . . of Tier 1 with power VDDopt1 and a power supply circuit 70b supplies the data latch circuits ADL, BDL, . . . of Tier 2 with power VDDopt2. A control signal SELa and an inverted control signal/SELa are inputted to the power supply circuit 70a.

In addition, a control signal SELb and an inverted control signal/SELb are inputted to the power supply circuit 70b. The configuration is otherwise the same as in the power supply circuit 70 according to the first embodiment shown in FIG. 7. Furthermore, components of the data latch circuits ADL and BDL of each tier are the same as the components of the data latch circuits ADL and BDL according to the first embodiment.

For example, when transferring data between the data latch circuits ADL and BDL of Tier 1, by setting the control signal SELa of the power supply circuit 70a to a high level, power VDDa with a higher voltage than the power VDD is supplied only to the data latch circuits ADL and BDL of Tier 1.

As a result, the power VDDa with a higher voltage than the power VDD is prevented from being supplied to the data latch circuits ADL and BDL of Tier 2 which is not performing data transfer and an increase in current consumption can be suppressed.

According to the configuration described above, the data latch circuit according to the present embodiment is capable of reducing a circuit area while increasing a transfer margin and a transfer rate in a similar manner to the data latch circuit according to the first embodiment. In addition, the data latch circuit according to the present embodiment is capable of further suppressing an increase in current consumption as compared to the data latch circuit according to the first embodiment.

### Third Embodiment

Next, a third embodiment will be described.

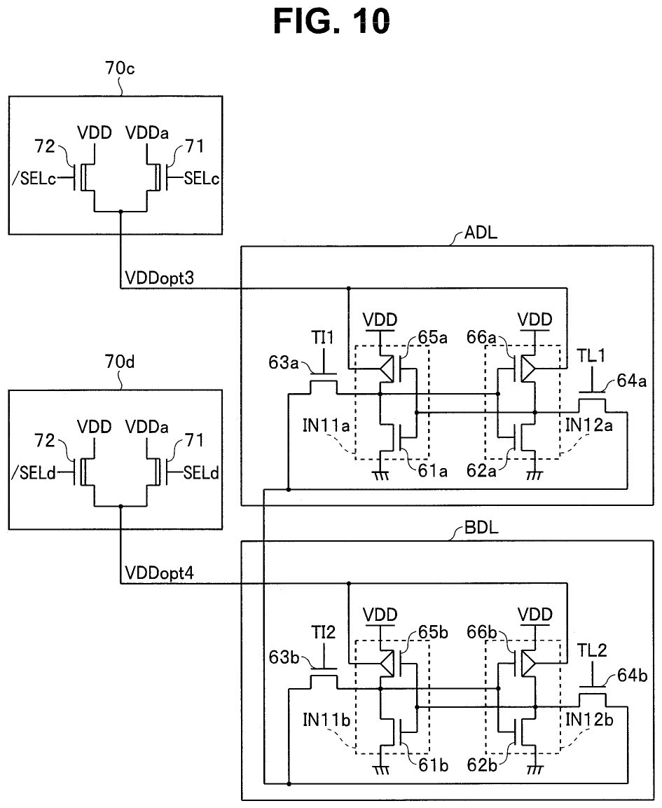

FIG. 10 is a circuit diagram showing an example of a configuration of a data latch circuit according to the third embodiment.

The third embodiment is a configuration in which a power supply circuit is provided for each data latch circuit.

As shown in FIG. 10, in the third embodiment, a power supply circuit 70c is provided with respect to a data latch circuit ADL and a power supply circuit 70d is provided with respect to a data latch circuit BDL.

The power supply circuit 70c supplies power VDDopt3 to the back gates of the PMOS transistors 65a and 66a of the data latch circuit ADL. In addition, the power supply circuit 70d supplies power VDDopt4 to the back gates of the PMOS transistors 65b and 66b of the data latch circuit BDL.

A control signal SELc and an inverted control signal/SELc are inputted to the power supply circuit 70c. In addition, a control signal SELd and an inverted control signal/SELd are inputted to the power supply circuit 70d. The configuration is otherwise the same as in the power supply circuit 70 according to the first embodiment shown in FIG. 7.

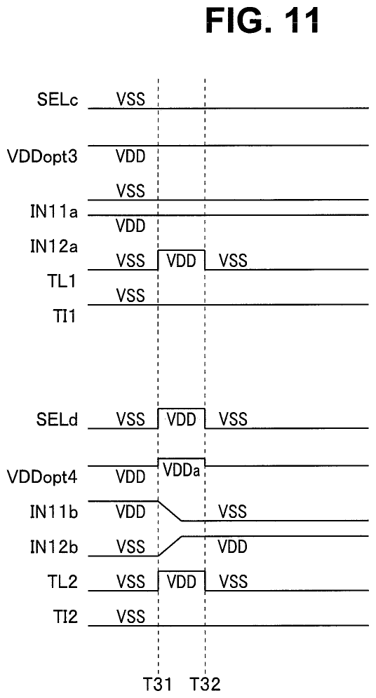

FIG. 11 is a waveform chart showing an example of a signal variation during data transfer according to the third embodiment.

The waveform chart shown in FIG. 11 is a waveform chart when transferring data from the data latch circuit ADL to the data latch circuit BDL. In FIG. 11, data is transferred between time points T31 to T32.

When transferring data from the data latch circuit ADL to the data latch circuit BDL, at the time point T31, control signals TL1 and TL2 are raised from a low level to a high level. Accordingly, the NMOS transistor 64a of the data latch circuit ADL and the NMOS transistor 64b of the data latch circuit BDL are turned on and an output of the inverter IN12a of the data latch circuit ADL is inputted to the inverter IN11b of the data latch circuit BDL.

The control signal SELc at a low level is inputted to the power supply circuit 70c when transferring data and when not transferring data. Accordingly, the NMOS transistor 72 of the power supply circuit 70c is turned on, the NMOS transistor 71 of the power supply circuit 70c is turned off, and the power VDD is inputted to the back gates of the PMOS transistors 65a and 66a of the data latch circuit ADL.

The control signal SELd at a low level is inputted to the power supply circuit 70d when not transferring data. Accordingly, the NMOS transistor 72 of the power supply circuit 70d is turned on, the NMOS transistor 71 of the power supply circuit 70d is turned off, and the power VDD is inputted to the back gates of the PMOS transistors 65b and 66b of the data latch circuit BDL.

On the other hand, the control signal SELd at a high level is inputted to the power supply circuit 70d when transferring data. Accordingly, the NMOS transistor 71 of the power supply circuit 70d is turned on, the NMOS transistor 72 of the power supply circuit 70d is turned off, and the power VDDa is inputted to the back gates of the PMOS transistors 65b and 66b of the data latch circuit BDL.

In other words, the power VDDa with a higher voltage than the power VDD is inputted only during data transfer to the back gates of the PMOS transistors 65b and 66b of the data latch circuit BDL to which data is transferred.

As described above, when transferring data from the data latch circuit ADL to the data latch circuit BDL, well potentials of the PMOS transistors 65b and 66b of the data latch circuit BDL to which the data is transferred are raised. On the other hand, when transferring data from the data latch circuit ADL to the data latch circuit BDL, well potentials of the PMOS transistors 65a and 66a of the data latch circuit to which the data is transferred are not raised and an increase in current consumption is suppressed.

According to the configuration described above, the data latch circuit according to the present embodiment is capable of reducing a circuit area while increasing a transfer margin and a transfer rate in a similar manner to the data latch circuit according to the first embodiment. In addition, the data latch circuit according to the present embodiment is capable of further suppressing an increase in current consumption as compared to the data latch circuit according to the first embodiment.

### Fourth Embodiment

Next, a fourth embodiment will be described.

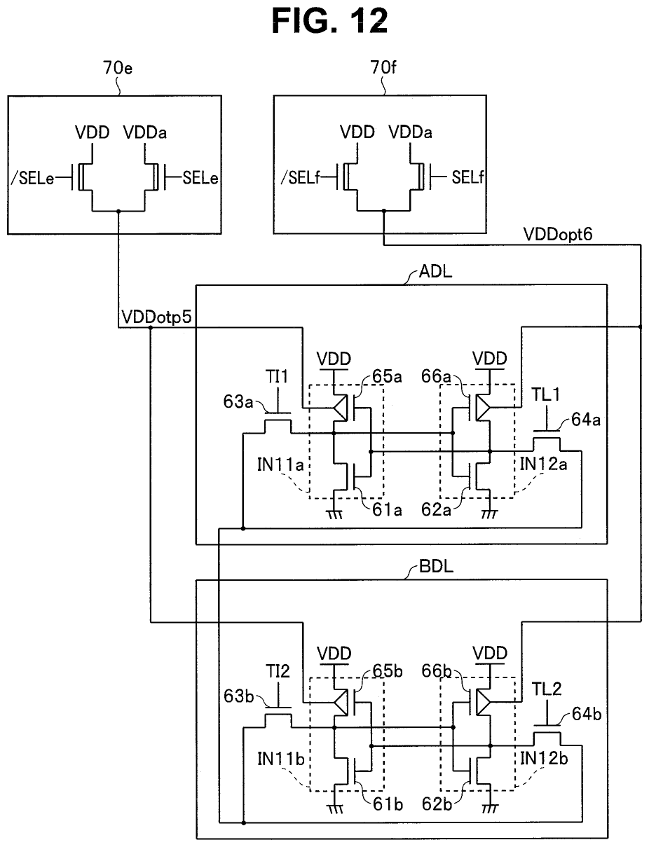

FIG. 12 is a circuit diagram showing an example of a configuration of a data latch circuit according to the fourth embodiment.

The fourth embodiment is a configuration in which a power supply circuit is provided for each PMOS transistor of a data latch circuit.

As shown in FIG. 12, in the fourth embodiment, a power supply circuit 70e is provided with respect to the PMOS transistors 65a and 65b of the data latch circuits ADL and BDL and a power supply circuit 70f is provided with respect to the PMOS transistors 66a and 66b of the data latch circuits ADL and BDL.

The power supply circuit 70e supplies power VDDopt5 to back gates of the PMOS transistors 65a and 65b of the data latch circuits ADL and BDL. The power supply circuit 70f supplies power VDDopt6 to back gates of the PMOS transistors 66a and 66b of the data latch circuits ADL and BDL.

A control signal SELe and an inverted control signal/SELe are inputted to the power supply circuit 70e. A control signal SELf and an inverted control signal/SELf are inputted to the power supply circuit 70f. The configuration is otherwise the same as in the power supply circuit 70 according to the first embodiment shown in FIG. 7.

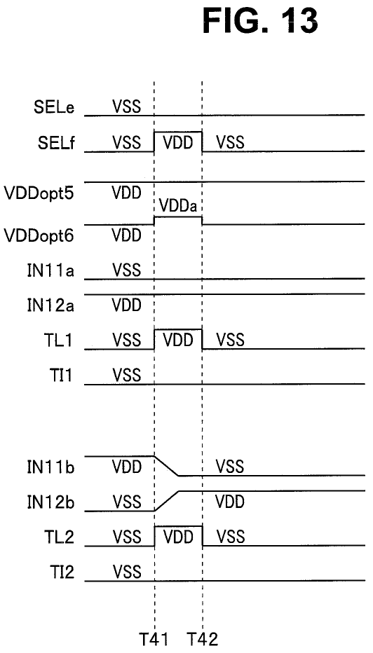

FIG. 13 is a waveform chart showing an example of a signal variation during data transfer according to the fourth embodiment.

The waveform chart shown in FIG. 13 is a waveform chart when transferring data from the data latch circuit ADL to the data latch circuit BDL. In FIG. 13, data is transferred between time points T41 to T42.

When transferring data from the data latch circuit ADL to the data latch circuit BDL, at the time point T41, control signals TL1 and TL2 are raised from a low level to a high level. Accordingly, the NMOS transistor 64a of the data latch circuit ADL and the NMOS transistor 64b of the data latch circuit BDL are turned on and an output of the inverter IN12a of the data latch circuit ADL is inputted to the inverter IN11b of the data latch circuit BDL.

The control signal SELe at a low level is inputted to the power supply circuit 70e when transferring data and when not transferring data. Accordingly, the

NMOS transistor 72 of the power supply circuit 70e is turned on, the NMOS transistor 71 of the power supply circuit 70e is turned off, and the power VDD is inputted to the back gates of the PMOS transistors 65a and 65b of the data latch circuits ADL and BDL.

The control signal SELf at a low level is inputted to the power supply circuit 70f when not transferring data. Accordingly, the NMOS transistor 72 of the power supply circuit 70f is turned on, the NMOS transistor 71 of the power supply circuit 70f is turned off, and the power VDD is inputted to the back gates of the PMOS transistors 66a and 66b of the data latch circuits ADL and BDL.

On the other hand, the control signal SELf at a high level is inputted to the power supply circuit 70f when transferring data. Accordingly, the NMOS transistor 71 of the power supply circuit 70f is turned on, the NMOS transistor 72 of the power supply circuit 70f is turned off, and the power VDDa is inputted to the back gates of the PMOS transistors 66a and 66b of the data latch circuits ADL and BDL.

In other words, the power VDDa with a higher voltage than the power VDD is input only during data transfer to the back gate of the PMOS transistor 66b of the data latch circuit BDL to which data is transferred.

As described above, when transferring data from the data latch circuit ADL to the data latch circuit BDL, a well potential of the PMOS transistor 66b of the data latch circuit BDL to which the data is transferred is raised. On the other hand, a well potential of the PMOS transistor 65b of the data latch circuit BDL is not raised and an increase in current consumption is suppressed.

According to the configuration described above, the data latch circuit according to the present embodiment is capable of reducing a circuit area while increasing a transfer margin and a transfer rate in a similar manner to the data latch circuit according to the first embodiment. In addition, the data latch circuit according to the present embodiment is capable of further suppressing an increase in current consumption as compared to the data latch circuit according to the first embodiment.

### Fifth Embodiment

Next, a fifth embodiment will be described.

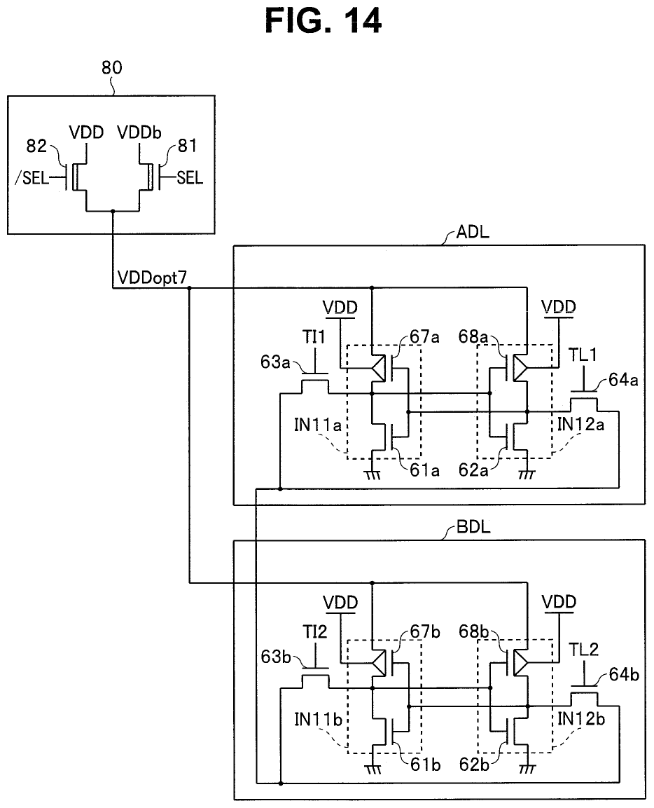

FIG. 14 is a diagram showing an example of a configuration of a data latch circuit according to the fifth embodiment.

As shown in FIG. 14, the data latch circuit ADL includes PMOS transistors 67a and 68a in place of the PMOS transistors 65a and 66a shown in FIG. 7. In addition, the data latch circuit BDL includes PMOS transistors 67b and 68b in place of the PMOS transistors 65b and 66b shown in FIG. 7.

Of the PMOS transistors 67a and 68a, power VDD is supplied to back gates and power VDDopt7 is supplied to sources. In a similar manner, of the PMOS transistors 67b and 68b, the power VDD is supplied to back gates and the power VDDopt7 is supplied to sources.

The power supply circuit 80 configured to generate the power VDDopt7 connects the power VDD and power VDDb of which a voltage is lower than the power VDD to each other using depletion NMOS transistors 81 and 82. The power VDD is, for example, 1.5 V, and the power VDDb is, for example, 1.0 V to 1.2 V. Note that the power supply circuit 80 is not limited to the depletion NMOS transistors 81 and 82 and may be configured using enhance NMOS transistors. In addition, the power supply circuit 80 may be provided inside the voltage generation circuit 25 or provided inside the sense amplifier unit group 28.

A control signal SEL is supplied to a gate of the NMOS transistor 81 and a control signal/SEL is supplied to a gate of the NMOS transistor 82. The control signal/SEL is an inversion of the control signal SEL. Accordingly, of the NMOS transistors 81 and 82, one is turned on while the other is turned off.

When the control signal SEL is at a high level, the NMOS transistor 81 is turned on, the NMOS transistor 82 is turned off, and the power VDDb is supplied to the sources of the PMOS transistors 67a, 68a, 67b, and 68b.

On the other hand, when the control signal is at a low level, the NMOS transistor 82 is turned on, the NMOS transistor 81 is turned off, and the power VDD is supplied to the sources of the PMOS transistors 67a, 68a, 67b, and 68b.

In the present embodiment, when transferring data between the data latch circuits ADL and BDL, source voltages of the PMOS transistors 67a, 68a, 67b, and 68b are lowered. Accordingly, in a similar manner to the first embodiment, by setting power supplied to the back gates relatively higher than power supplied to the sources and suppressing performances of the PMOS transistors 67a, 68a, 67b, and 68b, a transfer margin and a transfer rate are retained.

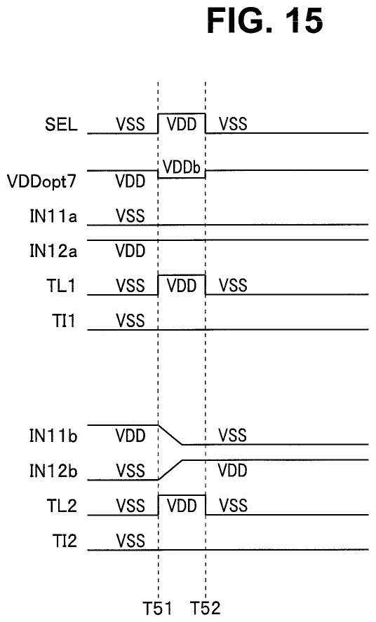

FIG. 15 is a waveform chart showing an example of a signal variation during data transfer according to the fifth embodiment.

The waveform chart shown in FIG. 15 is a waveform chart when transferring data from the data latch circuit ADL to the data latch circuit BDL. In FIG. 15, data is transferred between time points T51 to T52.

When transferring data from the data latch circuit ADL to the data latch circuit BDL, at the time point T51, control signals TL1 and TL2 are raised from a low level to a high level. Accordingly, the NMOS transistor 64a of the data latch circuit ADL and the NMOS transistor 64b of the data latch circuit BDL are turned on and an output of the inverter IN12a of the data latch circuit ADL is inputted to the inverter IN11b of the data latch circuit BDL.

In addition, the control signal SEL at a low level is inputted to the power supply circuit 80 when not transferring data. Accordingly, the NMOS transistor 82 is turned on, the NMOS transistor 81 is turned off, and the power VDD is inputted to the sources of the PMOS transistors 67a, 68a, 67b, and 68b.

On the other hand, the control signal SEL at a high level is inputted to the power supply circuit 80 when transferring data. Accordingly, the NMOS transistor 81 is turned on, the NMOS transistor 82 is turned off, and the power VDDb is inputted to the sources of the PMOS transistors 67a, 68a, 67b, and 68b.

In other words, the power VDDb with a lower voltage than the power VDD is inputted to the sources (first terminals) of the PMOS transistors 67a, 68a, 67b, and 68b only during data transfer. Accordingly, when transferring data between the data latch circuits ADL and BDL, a source voltage of the PMOS transistor 68b of the data latch circuit BDL to which the data is transferred is lowered. As a result, in the data latch circuit BDL, performance of the PMOS transistor 68b is suppressed and the transfer margin and the transfer rate can be increased.

Furthermore, with the data latch circuit ADL (and, similarly, the other data latch circuits), deleting the PMOS transistors 57a and 58a from the data latch circuit ADLx according to the comparative example results in a reduced area.

As described above, with the data latch circuit according to the present embodiment, a circuit area can be reduced while increasing a transfer margin and a transfer rate in a similar manner to the first embodiment.

### Sixth Embodiment

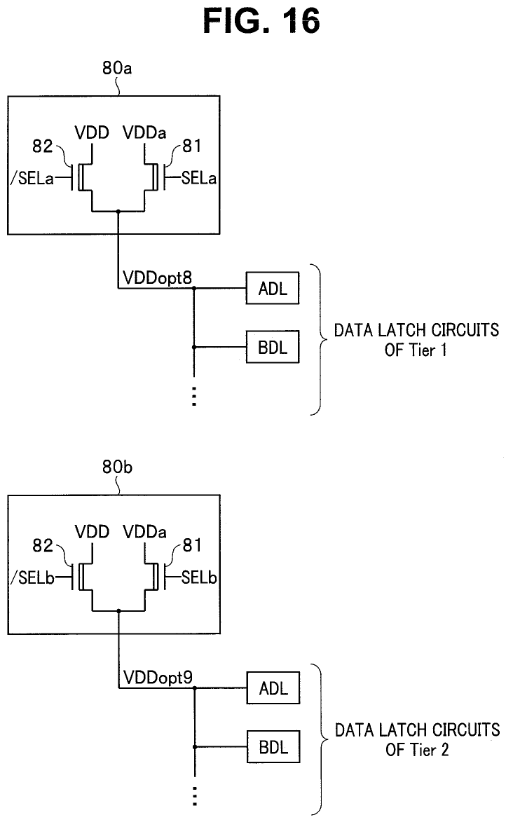

FIG. 16 is a diagram showing an example of a connection between a data latch circuit and a power supply circuit according to a sixth embodiment.

The sixth embodiment is a configuration in which power supplies are divided for each tier. Specifically, a power supply circuit 80a supplies data latch circuits ADL, BDL, . . . of Tier 1 with power VDDopt8. On the other hand, a power supply circuit 80b supplies data latch circuits ADL, BDL, . . . of Tier 2 with power VDDopt9.

A control signal SELa and an inverted control signal/SELa are inputted to the power supply circuit 80a. In addition, a control signal SELb and an inverted control signal/SELb are inputted to the power supply circuit 80b. The configuration is otherwise the same as in the power supply circuit 80 according to the fifth embodiment shown in FIG. 15. Furthermore, components of the data latch circuits ADL and BDL of each tier are the same as the components of the data latch circuits ADL and BDL according to the first embodiment.

For example, when transferring data between the data latch circuits ADL and BDL of Tier 1, by setting the control signal SELa of the power supply circuit 80a to a high level, power VDDb with a lower voltage than the power VDD is supplied only to the data latch circuits ADL and BDL of Tier 1.

Accordingly, when transferring data between the data latch circuits ADL and BDL, a source voltage of the PMOS transistor 68b of the data latch circuit BDL to which the data is transferred is lowered. As a result, in the data latch circuit BDL, performance of the PMOS transistor 68b is suppressed and a transfer margin and a transfer rate can be increased.

As described above, with the data latch circuit according to the present embodiment, a circuit area can be reduced while increasing a transfer margin and a transfer rate in a similar manner to the first embodiment.

### Seventh Embodiment

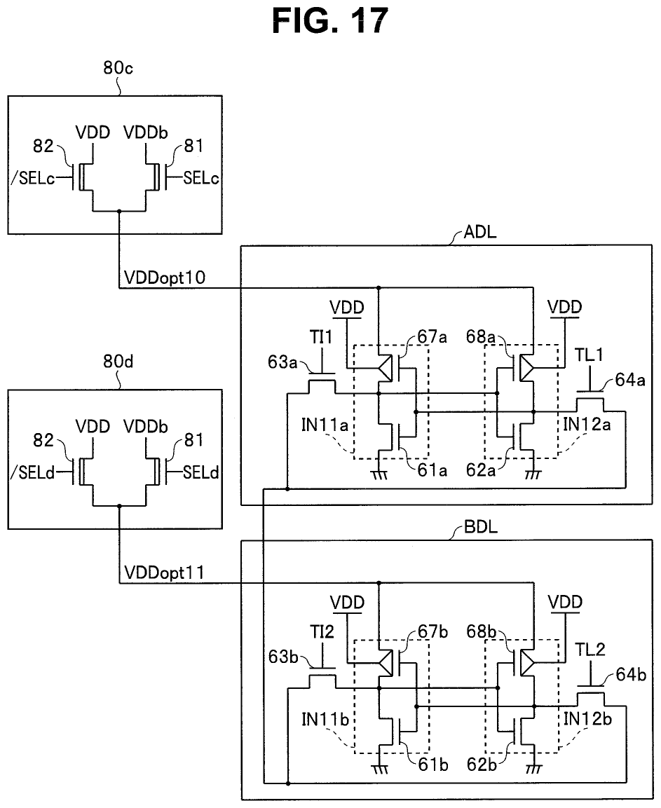

FIG. 17 is a diagram showing an example of a configuration of a data latch circuit according to a seventh embodiment.

The seventh embodiment is a configuration in which a power supply circuit is provided for each data latch circuit.

As shown in FIG. 17, a power supply circuit 80c is provided with respect to a data latch circuit ADL and a power supply circuit 80d is provided with respect to a data latch circuit BDL.

The power supply circuit 80c supplies power VDDopt10 to sources of PMOS transistors 67a and 68a of the data latch circuit ADL. The power supply circuit 80d supplies power VDDopt11 to sources of PMOS transistors 67b and 68b of the data latch circuit BDL.

A control signal SELc and an inverted control signal/SELc are inputted to the power supply circuit 80c. A control signal SELd and an inverted control signal/SELd are inputted to the power supply circuit 80d. The configuration is otherwise the same as in the power supply circuit 80 according to the fifth embodiment shown in FIG. 14.

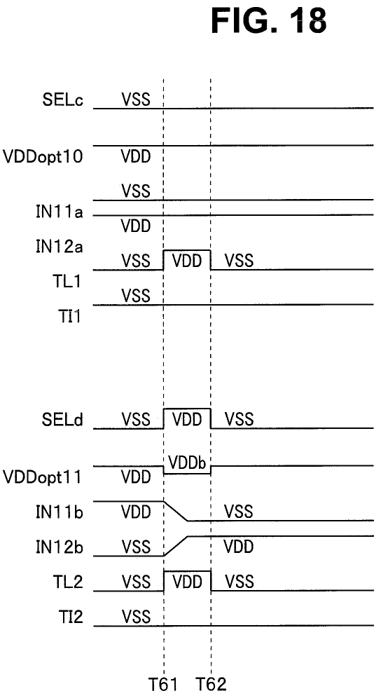

FIG. 18 is a waveform chart showing an example of a signal variation during data transfer according to the seventh embodiment.

The waveform chart shown in FIG. 18 is a waveform chart when transferring data from the data latch circuit ADL to the data latch circuit BDL. In FIG. 18, data is transferred between time points T61 to T62.

When transferring data from the data latch circuit ADL to the data latch circuit BDL, at the time point T61, control signals TL1 and TL2 are raised from a low level to a high level. Accordingly, the NMOS transistor 64a of the data latch circuit ADL and the NMOS transistor 64b of the data latch circuit BDL are turned on and the output of the inverter IN12a of the data latch circuit ADL is inputted to the inverter IN11b of the data latch circuit BDL.

The control signal SELc at a low level is inputted to the power supply circuit 80c when transferring data and when not transferring data. Accordingly, the

NMOS transistor 82 of the power supply circuit 80c is turned on, the NMOS transistor 81 of the power supply circuit 80c is turned off, and power VDD is inputted to the sources of the PMOS transistors 67a and 68a of the data latch circuit ADL.

The control signal SELd at a low level is inputted to the power supply circuit 80d when not transferring data. Accordingly, the NMOS transistor 82 of the power supply circuit 80d is turned on, the NMOS transistor 81 of the power supply circuit 80d is turned off, and the power VDD is inputted to the sources of the PMOS transistors 67b and 68b of the data latch circuit BDL.

On the other hand, the control signal SELd at a high level is inputted to the power supply circuit 80d when transferring data. Accordingly, the NMOS transistor 81 of the power supply circuit 80d is turned on, the NMOS transistor 82 of the power supply circuit 80d is turned off, and power VDDb is inputted to the sources of the PMOS transistors 67b and 68b of the data latch circuit BDL.

In other words, the power VDDb with a lower voltage than the power VDD is inputted only during data transfer to the sources of the PMOS transistors 67b and 68b of the data latch circuit BDL to which data is transferred.

Accordingly, when transferring data between the data latch circuits ADL and BDL, a source voltage of the PMOS transistor 68b of the data latch circuit BDL to which the data is transferred is lowered. As a result, in the data latch circuit BDL, performance of the PMOS transistor 68b is suppressed and a transfer margin and a transfer rate can be increased.

As described above, with the data latch circuit according to the present embodiment, a circuit area can be reduced while increasing a transfer margin and a transfer rate in a similar manner to the first embodiment.

### Eighth Embodiment

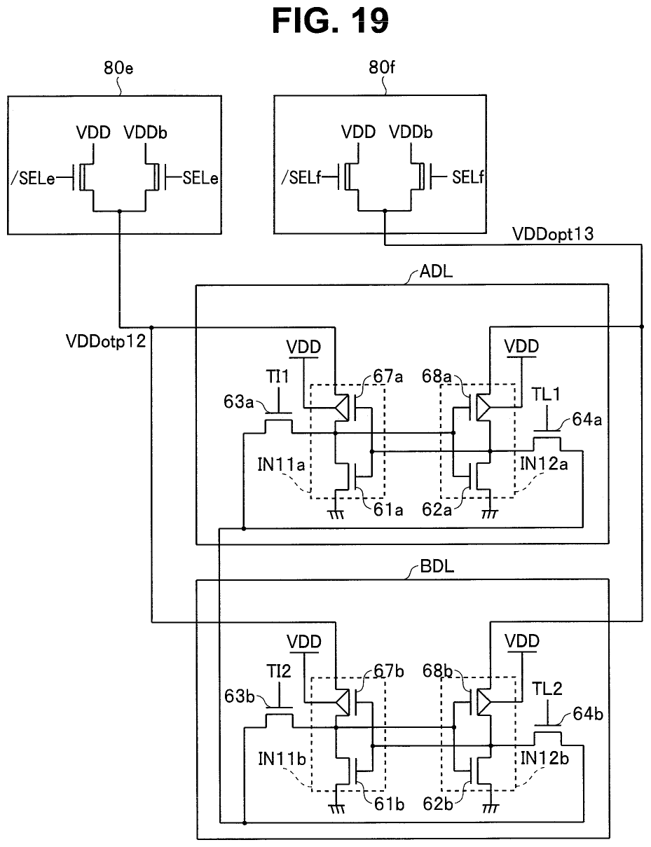

FIG. 19 is a diagram showing an example of a configuration of a data latch circuit according to an eighth embodiment.

The eighth embodiment is a configuration in which a power supply circuit is provided for each PMOS transistor of a data latch circuit.

As shown in FIG. 19, a power supply circuit 80e is provided with respect to PMOS transistors 67a and 67b of the data latch circuits ADL and BDL and a power supply circuit 80f is provided with respect to PMOS transistors 68a and 68b of the data latch circuits ADL and BDL.

The power supply circuit 80e supplies power VDDopt12 to sources of PMOS transistors 65a and 65b of the data latch circuits ADL and BDL. The power supply circuit 80f supplies power VDDopt13 to sources of the PMOS transistors 68a and 68b of the data latch circuits ADL and BDL.

A control signal SELe and an inverted control signal/SELe are inputted to the power supply circuit 80e. A control signal SELf and an inverted control signal/SELf are inputted to the power supply circuit 80f. The configuration is otherwise the same as in the power supply circuit 80 according to the fifth embodiment shown in FIG. 14.

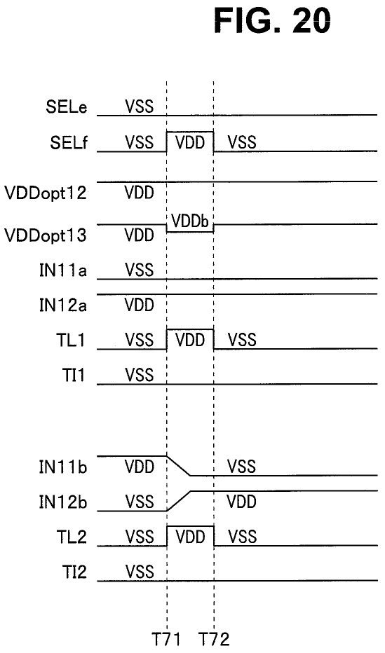

FIG. 20 is a waveform chart showing an example of a signal variation during data transfer according to the eighth embodiment.

The waveform chart shown in FIG. 20 is a waveform chart when transferring data from the data latch circuit ADL to the data latch circuit BDL. In FIG. 20, data is transferred between time points T71 to T72.

When transferring data from the data latch circuit ADL to the data latch circuit BDL, at the time point T71, control signals TL1 and TL2 are raised from a low level to a high level. Accordingly, the NMOS transistor 64a of the data latch circuit ADL and the NMOS transistor 64b of the data latch circuit BDL are turned on and an output of the inverter IN12a of the data latch circuit ADL is inputted to the inverter IN11b of the data latch circuit BDL.

The control signal SELe at a low level is inputted to the power supply circuit 80e when transferring data and when not transferring data. Accordingly, the NMOS transistor 82 of the power supply circuit 80e is turned on, the NMOS transistor 81 of the power supply circuit 80e is turned off, and power VDD is inputted to the sources of the PMOS transistors 67a and 67b of the data latch circuits ADL and BDL.

The control signal SELf at a low level is inputted to the power supply circuit 80f when not transferring data. Accordingly, the NMOS transistor 82 of the power supply circuit 80f is turned on, the NMOS transistor 81 of the power supply circuit 80f is turned off, and the power VDD is inputted to the sources of the PMOS transistors 68a and 68b of the data latch circuits ADL and BDL.

On the other hand, the control signal SELf at a high level is inputted to the power supply circuit 80f when transferring data. Accordingly, the NMOS transistor 81 of the power supply circuit 80f is turned on, the NMOS transistor 82 of the power supply circuit 80f is turned off, and power VDDb is inputted to the sources of the PMOS transistors 68a and 68b of the data latch circuits ADL and BDL.

In other words, the power VDDb with a lower voltage than the power VDD is inputted only during data transfer to the sources of the PMOS transistors 68a and 68b of the data latch circuits ADL and BDL to which data is transferred.

Accordingly, when transferring data between the data latch circuits ADL and BDL, a source voltage of the PMOS transistor 68b of the data latch circuit BDL to which the data is transferred is lowered. As a result, in the data latch circuit BDL, performance of the PMOS transistor 68b is suppressed and a transfer margin and a transfer rate can be increased.

As described above, with the data latch circuit according to the present embodiment, a circuit area can be reduced while increasing a transfer margin and a transfer rate in a similar manner to the first embodiment.

While certain embodiments have been described, these embodiments have been presented by way of example only, and are not intended to limit the scope of the inventions. Indeed, the novel devices and systems described herein may be embodied in a variety of other forms; furthermore, various omissions, substitutions and changes in the form of the devices and systems described herein may be made without departing from the spirit of the inventions. The accompanying claims and their equivalents are intended to cover such forms or modifications as would fall within the scope and spirit of the inventions.

What is claimed is:

1. A data latch circuit, comprising:
a first circuit in which a first transistor with a first conductivity type and a second transistor with a second conductivity type that differs from the first conductivity type are connected in series and which is configured to store a first logical value; and
a second circuit in which a third transistor with the first conductivity type and a fourth transistor with the second conductivity type are connected in series and which is configured to store a second logical value being an inversion of the first logical value, wherein
one of a first voltage and a second voltage that differs from the first voltage can be applied to back gates of the first transistor and the third transistor and a third voltage can be applied to sources of the first transistor and the third transistor.

2. The data latch circuit according to claim 1, wherein
when data is stored in the first circuit and the second circuit, the first voltage can be applied to the back gates of the first transistor and the third transistor and the third voltage can be applied to the sources of the first transistor and the third transistor, and
when the data is transferred from the first circuit and the second circuit, a second voltage that is higher than the first voltage can be applied to the back gates of the first transistor and the third transistor, the third voltage can be applied to the sources of the first transistor and the third transistor, and the data is based on the first logical value and the second logical value.

3. A data latch circuit, comprising:
a first circuit in which a first transistor with a first conductivity type and a second transistor with a second conductivity type that differs from the first conductivity type are connected in series and which is configured to store a first logical value; and
a second circuit in which a third transistor with the first conductivity type and a fourth transistor with the second conductivity type are connected in series and which is configured to store a second logical value being an inversion of the first logical value, wherein
one of a first voltage and a second voltage that differs from the first voltage can be applied to sources of the first transistor and the third transistor and a third voltage can be applied to back gates of the first transistor and the third transistor.

4. The data latch circuit according to claim 3, wherein
when data is stored in the first circuit and the second circuit, the first voltage can be applied to the sources of the first transistor and the third transistor and the third voltage can be applied to the back gates of the first transistor and the third transistor, and
when the data is transferred from the first circuit and the second circuit, a second voltage that is lower than the first voltage can be applied to the sources of the first transistor and the third transistor, and the third voltage can be applied to the back gates of the first transistor and the third transistor.

5. The data latch circuit according to claim 1, wherein
the first voltage and the third voltage have a same potential.

6. A semiconductor device, comprising:
the data latch circuit according to claim 1; and
a power supply circuit configured to be capable of applying the first voltage or the second voltage to the back gates or the sources of the first transistor and the third transistor of the data latch circuit.

7. The semiconductor device according to claim 6, wherein
the power supply circuit is configured to be capable of applying the first voltage or the second voltage to the back gates of the first transistor and the third transistor,
the power supply circuit is configured to be capable of applying the first voltage to the back gates of the first transistor and the third transistor when the data is stored in the first circuit and the second circuit, and
the power supply circuit is configured to be capable of applying the second voltage to the back gates of the first transistor and the third transistor when the data is transferred from the first circuit and the second circuit.

8. The semiconductor device according to claim 6, wherein
the power supply circuit is configured to be capable of applying the first voltage or the second voltage to the sources of the first transistor and the third transistor,
the power supply circuit is configured to be capable of applying the first voltage to the sources of the first transistor and the third transistor when the data is stored in the first circuit and the second circuit, and
the power supply circuit is configured to be capable of applying the second voltage to the sources of the first transistor and the third transistor when the data is transferred from the first circuit and the second circuit.

9. The semiconductor device according to claim 6, comprising
the data latch circuit in plurality, wherein
the power supply circuit is configured to be capable of applying power to the data latch circuit in plurality.

10. The semiconductor device according to claim 6, comprising
the power supply circuit in plurality, and
the data latch circuit in plurality, wherein
a first power supply circuit among the power supply circuit in plurality is configured to be capable of applying power to a first data latch circuit among the data latch circuit in plurality, and a second power supply circuit among the power supply circuit in plurality is configured to be capable of applying power to a second data latch circuit among the data latch circuit in plurality.

11. The semiconductor device according to claim 6, comprising
the power supply circuit in plurality, wherein
a first power supply circuit among the power supply circuit in plurality is configured to be capable of applying power to the first transistor, and a second power supply circuit among the power supply circuit in plurality is configured to be capable of applying power to the third transistor.

12. A semiconductor storage device, comprising:
a memory cell transistor;
a bit line connected to the memory cell transistor;
a sense amplifier unit which is connected to the bit line and which includes the data latch circuit according to claim 1, and
a power supply circuit configured to be capable of applying the first voltage or the second voltage to the data latch circuit.
